(19) United States
(12) Patent Application Publication
(10) Pub. No.: US 2010/0090308 A1
(43) Pub. Date: Apr. 15, 2010

(54) METAL-OXIDE-METAL CAPACITORS WITH BAR VIAS

(76) Inventors: Charu Sardana, San Jose, CA (US); Albert Ratnakumar, San Jose, CA (US); Bradley Jensen, San Jose, CA (US); Jeffrey T. Watt, Palo Alto, CA (US)

Correspondence Address: Treyz Law Group, 870 Market Street, Suite 984, San Francisco, CA, 94102, US

(21) Appl. No.: 12/249,901

(22) Filed: Oct. 10, 2008

(51) Int. Cl. H01L 29/92

(52) U.S. Cl. 257/532; 257/E29.343

(57) ABSTRACT

Metal-oxide-metal capacitors with bar vias are provided for integrated circuits. The capacitors may be formed in the interconnect layers of integrated circuits. Stacked bar vias and metal lines in the interconnect layers may be connected to form conductive vertical plates that span multiple interconnect layers. The capacitors with bar vias may be formed by placing multiple vertical plates formed from stacked bar vias and metal lines parallel to each other, alternating the polarity of adjacent vertical parallel plates to form multiple parallel plate capacitors. The parallel plates may be interconnected to form first and second terminals in a capacitor.

### BACKGROUND

The present invention relates to integrated circuits, and more particularly, to metal-oxide-metal capacitors in integrated circuits.

Metal-oxide-metal capacitors can be formed in the interconnect layers of integrated circuits. These capacitors are typically formed from structures in multiple interconnect layers that utilize both a vertical and a lateral electric field component. For example, capacitors such as metal-comb-woven capacitors and horizontal-metal-comb capacitors have been used. Another type of capacitor that has been implemented in integrated circuits is a perforated vertical parallel plate capacitor. In the perforated vertical parallel plate capacitor design, perforated vertical plates are formed by interconnecting metal lines in vertically-adjacent interconnect layers with multiple vias. Perforated vertical plates form a perforated parallel plate capacitor when they are placed adjacent to each other and opposite charges are applied to the adjacent perforated plates.

As integrated circuits are scaled down to smaller sizes, conventional metal-oxide-metal capacitors can consume an excessively large fraction of the available area in the interconnection layers of integrated circuits. It would therefore be desirable to be able to provide metal-oxide-metal capacitors in integrated circuits that exhibit improved capacitance in a given area.

### SUMMARY

In accordance with the present invention, metal-oxide-metal capacitors in integrated circuits are provided that exhibit increased capacitance. The capacitors may be formed in the interconnect layers of integrated circuits. Each interconnect layer may be formed substantially of dielectric with metal lines and vias formed in the dielectric. Interconnect layers may include metal-layer interconnect layers and via-layer interconnect layers.

Metal lines may be formed in metal-layer interconnect layers. Vias and bar vias may be formed in the via-layer interconnect layers. With one suitable arrangement, a bar via may be implemented using an elongated via structure. An elongated via structure may be a via with a length that is at least twice its width. For example, an elongated via structure may have a length that is two times its width, five times its width, ten times its width, or more than ten times its width. The metal lines, vias, and bar vias may be formed from a conductive material such as copper.

The capacitors of the present invention may be formed over multiple interconnect layers. In the metal-layer portion of each interconnect layer that is used to form a capacitor, multiple metal lines may be formed parallel to each other. Multiple bar vias may also be formed in the appropriate via-layer interconnect layer. Each bar via may vertically overlap and be electrically connected along its length to a respective one of the metal lines. Each electrically connected bar via and metal line may be electrically connected to non-adjacent sets of bar vias and metal lines. For example, the first bar via and metal line in each interconnect layer may be connected to the third bar via and metal line, the fifth bar via and metal line, etc. During operation, the odd-numbered sets of bar vias and metal lines may be at a first voltage. The second bar via and metal line may be connected to the fourth bar via and metal line, the sixth bar via and metal line, etc. The even-numbered sets of vias and metal lines may be at a second voltage.

Any suitable number of interconnect layers with the interconnected sets of bar vias and metal lines may be vertically stacked to form a capacitor. When interconnect layers are vertically stacked, the bar vias of the lower level will be electrically connected to the metal lines of the upper level.

Further features of the invention, its nature and various advantages will be more apparent from the accompanying drawings and the following detailed description of the preferred embodiments.

### BRIEF DESCRIPTION OF THE DRAWINGS

FIG. 1 is a perspective view of a conventional metal-comb-woven capacitor.

FIG. 2 is a perspective view of a conventional horizontal-metal-comb capacitor.

FIG. 3 is a perspective view of a conventional perforated vertical parallel plate capacitor.

FIG. 4 is a perspective view of an illustrative vertical parallel plate capacitor that may be formed using bar vias in accordance with an embodiment of the present invention.

FIG. 5 is a cross-sectional view of an illustrative integrated circuit with interconnect layers in which a vertical parallel plate capacitor is formed using bar vias in accordance with an embodiment of the present invention.

FIG. 6 is a perspective view of an illustrative vertical parallel plate capacitor with bar vias in which metal lines may be formed using a first lithography-and-etch sequence and the bar vias may be formed using a second lithography-and-etch sequence in accordance with an embodiment of the present invention.

FIGS. 7A, 7B, 7C, 7D, 7E, and 7F are cross-sectional views of the vertical parallel plate capacitor of FIG. 6 in illustrative stages of formation in accordance with an embodiment of the present invention.

FIG. 8 is a flowchart of illustrative steps involved in forming the vertical parallel plate capacitor of FIG. 6 in accordance with an embodiment of the present invention.

FIG. 9 is a perspective view of an illustrative vertical parallel plate capacitor with bar vias in which metal lines and the bar vias may be formed using a single lithography-and-etch sequence in accordance with an embodiment of the present invention.

FIGS. 10A, 10B, 10C, 10D, and 10E are cross-sectional views of the vertical parallel plate capacitor of FIG. 9 in illustrative stages of formation in accordance with an embodiment of the present invention.

FIG. 11 is a flowchart of illustrative steps involved in forming the vertical parallel plate capacitor of FIG. 9 in accordance with an embodiment of the present invention.

FIGS. 12A, 12B, 12C, 12D, and 12E are cross-sectional views of a vertical parallel plate capacitor, which may be formed using a damascene process in illustrative stages of formation in accordance with an embodiment of the present invention.

FIG. 13 is a flowchart of illustrative steps involved in forming the vertical parallel plate capacitor of FIGS. 12A, 12B, 12C, 12D, and 12E in accordance with an embodiment of the present invention.

FIG. 14 is a top view of an illustrative capacitor with bar vias showing how metal lines and the bar vias to which they are electrically connected may be shorted together to form first and second terminals in accordance with an embodiment of the present invention.

### DETAILED DESCRIPTION

The present invention relates to integrated circuit metal-oxide-metal capacitors. Metal-oxide-metal capacitors in accordance with embodiments of the present invention may be incorporated into any suitable integrated circuit, such as an application-specific-integrated circuit, a digital signal processing circuit, a microprocessor, a programmable logic device integrated circuit, or any other suitable analog or digital circuit.

Metal-oxide-metal capacitors may be formed in the interconnect layers of an integrated circuit. The capacitance of metal-oxide-metal capacitors can be modeled as a number of parallel plate capacitors. The capacitance of a parallel plate capacitor is proportional to the dielectric constant of the material filling the capacitor and the area of the overlapping parallel plates, and is inversely proportional to the separation of the parallel plates.

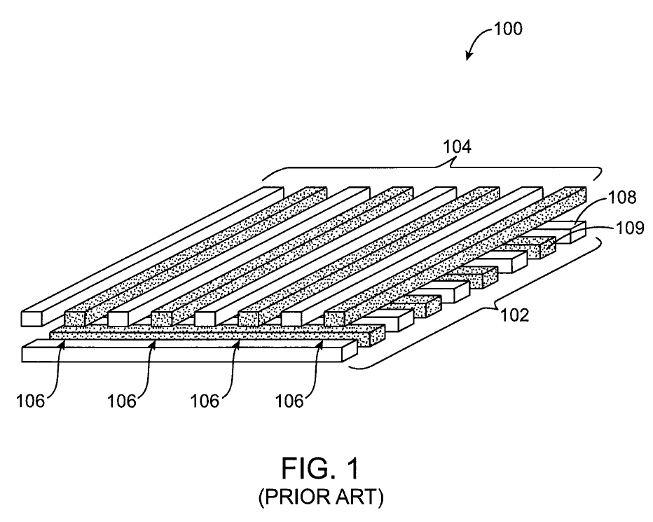

A conventional metal-comb-woven capacitor 100 is shown in FIG. 1. The conventional metal-comb-woven capacitor 100 is formed from groups of parallel metal lines in sequential metal layers. Each set of lines is rotated 90 degrees with respect to lines in the adjacent metal layer. FIG. 1 shows a capacitor 100 with two metal layers 102 and 104. Each of the metal layers 102 and 104 of capacitor 100 is formed from adjacent metal lines of alternating polarity. In the drawing of FIG. 1, the set of darker lines such as line 109 are shorted together and are associated with a first terminal of capacitor 100, whereas the set of lighter lines such as line 108 are shorted together and are associated with a second terminal of capacitor 100. The metal layers 102 and 104 are each formed in a respective metal-layer interconnect layer in an integrated circuit.

Capacitances that result between structures that reside within a common interconnect layer are sometimes referred to as horizontal capacitances. Capacitances that result between structures that reside in adjacent interconnect layers are sometimes referred to as vertical capacitances. The primary contribution to the capacitance of the capacitor 100 is the horizontal capacitance between adjacent metal lines within a particular interconnect layer.

A secondary contribution to the capacitance of the capacitor 100 results from the vertical capacitance provided by the overlapping of metal layers that are rotated 90 degrees from each other such as metal layers 102 and 104. At each of the points at which a metal line of a first polarity (e.g., metal lines such as line 108) overlaps a metal line in an adjacent interconnect layer of a second polarity (e.g., metal lines such as line 109) a vertical capacitance is created. This vertical capacitance in capacitor 100 is minor relative to the horizontal capacitance in each interconnect layer in capacitor 100. Arrows 106 illustrate where the vertical capacitances between metal lines in adjacent interconnect layers are created for the metal line in layer 102 in the foreground of FIG. 1.

While not shown in FIG. 1, the metal lines in layers 102 and 104 are interconnected with other lines having the same polarity (e.g., the darker metal lines may be connected together and the lighter metal lines may be connected together) so that capacitor 100 forms a single capacitive structure. The connections between metal lines of a common polarity in each interconnect layer form a comb-like structure that extends from the ends of the metal lines in a particular layer (e.g., forming a “toothed” portion of the comb-like structure). The connection structure may also wrap around to one side of metal lines (e.g., forming the “handle” portion of the comb-like structure), facilitating connection between adjacent interconnect layers and their respective comb-like metal line interconnect structures (e.g., adjacent comb-like metal line interconnect structures may be connected by multiple via interconnects).

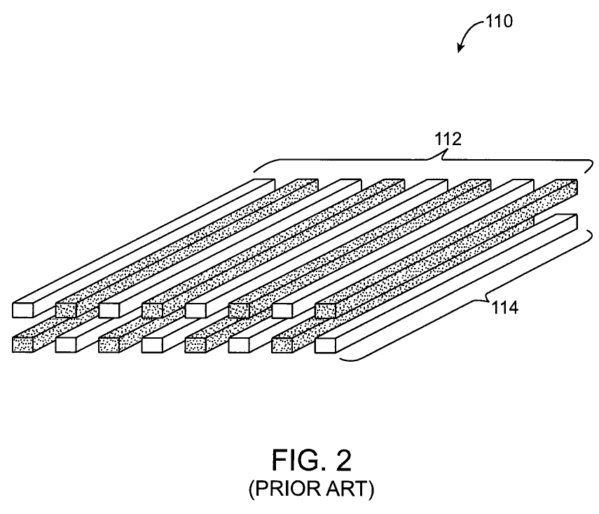

Another conventional capacitor 110 is shown in FIG. 2. Capacitor 110 is a horizontal-metal-comb capacitor in which parallel metal lines in adjacent interconnect layers are shifted so that they are offset. The amount of horizontal capacitance produced by capacitor 110 is similar to the amount of horizontal capacitance produced by capacitor 100 of FIG. 1.

With the arrangement of FIG. 2, however, the vertical capacitance of capacitor 110 is increased with respect to the vertical capacitance of capacitor 100 in FIG. 1. The vertical capacitance of the capacitor 110 results primarily from the overlap between the metal lines in a particular metal layer and the metal lines with opposite polarity that are in an adjacent metal layer (e.g., either directly below or directly above the particular metal layer).

FIG. 3 shows a conventional perforated vertical parallel plate capacitor 116. The perforated vertical parallel plate capacitor 116 is formed from parallel metal lines of alternating polarity. The metal lines are formed in multiple metal layers and the polarity of vertically-adjacent metal lines is aligned, unlike the configuration of capacitor 110 of FIG. 2. These vertically-connected metal lines are then interconnected with multiple vias such as vias 118 and 119 which forms a perforated vertical parallel plate design as shown in FIG. 3.

In the design of capacitor 116, there is no significant vertical capacitance (i.e., capacitance across multiple interconnect layers of opposing polarity). Rather, the majority of the capacitance of capacitor 116 is formed in the horizontal plane between the parallel metal lines of opposite polarity. In addition, the multiple vias of capacitor 116 can contribute to the horizontal capacitance of capacitor 116.

As integrated circuits are scaled down to ever smaller sizes, the conventional capacitors of FIGS. 1-3 can consume excessively large amounts of available circuit area. In accordance with embodiments of the present invention, vertical parallel plate capacitors with bar vias are provided. The vertical parallel plate capacitors with bar vias of the present invention may have an increased capacitance per unit area (per unit volume), relative to conventional capacitors. For example, vertical parallel plate capacitors with bar vias of the present invention may have a capacitance that is approximately 19% to 30% larger for a given volume than the conventional woven-metal-comb capacitor 100 of FIG. 1.

The capacitance of the vertical parallel plate capacitors with bar vias in capacitor structures in accordance with embodiments of the present invention may be modeled as the capacitance of a number of parallel plate capacitors. The capacitance of a parallel plate capacitor with two parallel plates generally increases as the dielectric constant of the material between the two parallel plates is increased, as the area of the parallel plates is increased, and as the parallel plates are brought closer together.

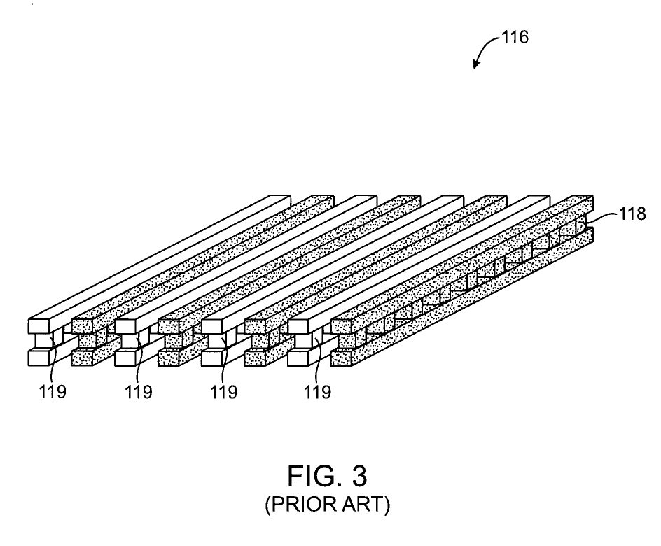

As shown in FIG. 4, a vertical parallel plate capacitor 10 may have parallel lines formed from metal-filled trenches such as lines 12, 14, 16, and 18 in two or more interconnect layers connected by respective bar vias such as bar vias 13 and 15. The parallel metal lines may be configured to alternate in polarity across an interconnect layer. With another suitable arrangement, the parallel metal lines may be configured to alternate between two different voltages across an interconnect layer. For example, lines 12 and 14 in the upper interconnect layer illustrated in FIG. 4 may be of opposite polarity (i.e., the conductive lines in these trenches may be associated with respective first and second capacitor terminals). While lines 12, 14, 16, and 18 are shown in FIG. 4 as being wider than bar vias 13 and 15, if desired the width of the lines of the capacitor 10 may be similar to or even less than the width of the bar vias of the capacitor 10.

There may be any suitable number of parallel metal lines and each metal line may be of any suitable length. Generally, capacitors formed using a larger number of parallel plates (i.e., metal lines and bar vias) or formed using larger parallel plates (i.e., longer metal lines and bar vias when the thickness of the interconnect layers is held constant) will have increased capacitance.

The distance between parallel metal lines (i.e., parallel plates) of a capacitor such as capacitor 10 can be adjusted to configure its capacitance. For example, when a circuit designer desires to maximize the capacitance of capacitor 10, the circuit designer may place the parallel metal lines 12 and 14 and bar vias 13 and 15 of capacitor 10 as close to each other as possible within any relevant manufacturing constraints (i.e., at the minimum spacing permitted by the design rules for the semiconductor manufacturing process that is used to fabricate capacitor 10 and the rest of the integrated circuit).

In the example shown in FIG. 4, capacitor 10 has two levels of metal lines connected by a single layer of bar vias. The lower level of lines which includes lines 16 and 18 is connected to the upper level of lines 12 and 14 by bar vias 13 and 15, respectively. In general, capacitors such as capacitor 10 may be formed over any suitable number of interconnect layers (e.g., with two or more layers of parallel metal lines each layer connected to the adjacent layer by multiple bar vias).

Because the bar vias of capacitor 10 are shorted to the metal lines to which they are physically connected, the bar vias essentially extend the metal lines vertically and increase the area of the metal lines in the vertical plane. By increasing the area of the metal lines using bar vias, the capacitance of the capacitor 10 is increased per unit volume relative to conventional capacitors.

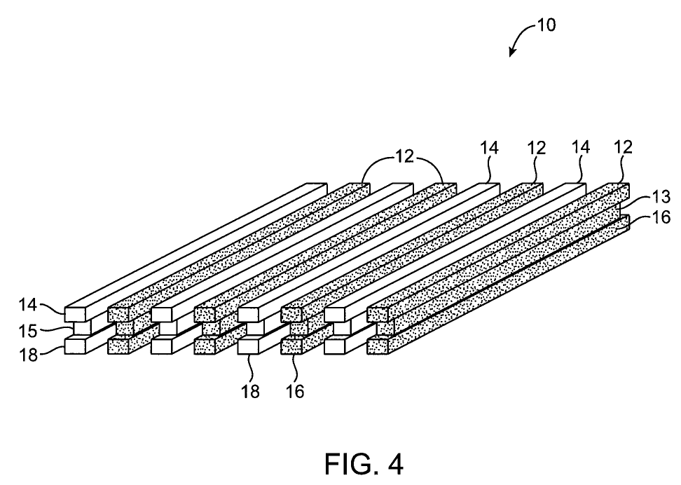

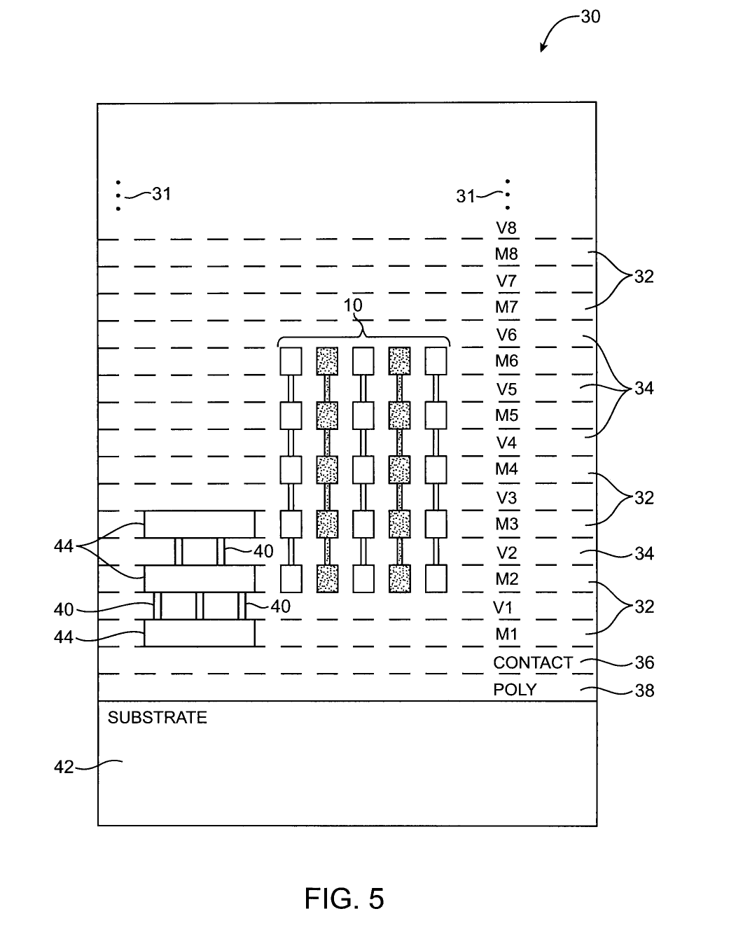

As shown in the cross-sectional side view of FIG. 5, the capacitor 10 may be formed in a dielectric stack 30 on an integrated circuit. Elsewhere on the integrated circuit of which the capacitor 10 of FIG. 4 is a part, the dielectric stack typically contains interconnect routing structures that route signals between various components and circuits on the integrated circuit.

The dielectric stack begins at the upper surface of integrated circuit substrate 42. The integrated circuit substrate 42 is typically formed from crystalline silicon. Transistors, diodes, and other active devices may be formed in substrate 42. Signals are then routed between these devices using the routing capabilities of interconnect layers in the dielectric stack 30. For example, the dielectric stack 30 may include portions with interconnect circuitry such as metal-layer interconnects 44 and via-layer vias 40.

The dielectric stack 30 includes a number of metal interconnect layers 32. In FIG. 5, there are eight metal interconnect layers 32 labeled “M1” to “M8” because the fabrication process used to form the circuit of FIG. 5 uses eight metal interconnect layers 32. However, as illustrated by dots 31, there may be any suitable number of metal interconnect layers 32. In the example of FIG. 5, the capacitor 10 is formed in portions of the M2, M3, M4, M5, and M6 metal interconnect layers and portions of the via layers between those interconnect layers.

During fabrication, the metal interconnect layers are patterned to form conductive routing paths, which are sometimes called interconnects. These paths are typically less that a micron in width and are used to interconnect devices on the integrated circuit so that they perform desired circuit functions. Via interconnect layers 34 are generally used to form short column-shaped vertical conductors called vias that are used to connect interconnects in adjacent layers. The via interconnect layers 34 are labeled V1, V2 . . . V8.

As shown in FIG. 5, a via 40 in via interconnect layer V1 can be used to connect an interconnect in the M1 layer to an interconnect in the M2 layer. Similarly, a via 40 in the V2 via layer may be used to interconnect an M2 interconnect to an M3 interconnect.

When used to connect interconnects in adjacent metal interconnect layers, vias 40 are sometimes used in isolation. For example, if a particular routing path requires that an electrical connection be made between a line in the M4 layer and a line in the M5 layer, these lines can typically be electrically connected to each other using a single via. Only a few vias are shown in FIG. 5 to avoid over-complicating FIG. 5. In general, there are many more vias between each layer. Typical vias have lateral dimensions on the order of 0.5 μm or less.

In both the metal interconnect layers 32 and the via interconnect layers 34, some of the layer makes up conductive pathways and some of the layer is insulating dielectric (i.e., silicon oxide).

There is typically a polysilicon layer 38 adjacent to the silicon substrate. This layer is generally patterned to form transistor gates and other device structures. Contact layer 36 is a via-type layer in which short vertical conductors are formed using tungsten plugs. The tungsten plugs in contact layer 36 are used to electrically connect patterned polysilicon in layer 38 to patterned metal in the M1 metal interconnect layer.

The structures shown in FIG. 5 are merely illustrative. Any suitable metal and via interconnect patterns and any suitable substrate structures may be formed in the dielectric stack 30.

In the example of FIG. 5, the dielectric stack 30 includes structures formed from a polysilicon layer, a contact layer, eight metal interconnect layers (M1, M2 . . . ), and eight via interconnect layers (V1, V2 . . . ). This is merely illustrative. For example, the capacitors of the present invention may be implemented in dielectric stacks containing any suitable number of metal and via interconnect layers (e.g., fewer than seven layers, seven layers, eight layers, nine layers, or more than nine layers). In a typical arrangement, there are about eight to ten metal interconnect layers and about seven to nine via interconnect layers. As improvements are made to semiconductor fabrication processes in the future, more interconnect layers may be used on an integrated circuit.

The metal portions of interconnect layers 32 and via interconnect layers 34 may be formed from any suitable material. With one suitable arrangement, the conductive material in the metal interconnect layers and via layers of dielectric stack 30 are formed from copper. The conductive material in the contact layer is typically tungsten but, in general, may be formed from any suitable material. The conductive material in the poly layer is typically polysilicon (e.g., doped silicided polysilicon). The insulating material in the metal and via interconnect layers and in the contact and polysilicon layers may be silicon dioxide or any other suitable insulator. In general, the choice of materials for the dielectric stack 30 is dictated by the semiconductor fabrication process being used to fabricate the integrated circuit in which capacitor 10 is formed.

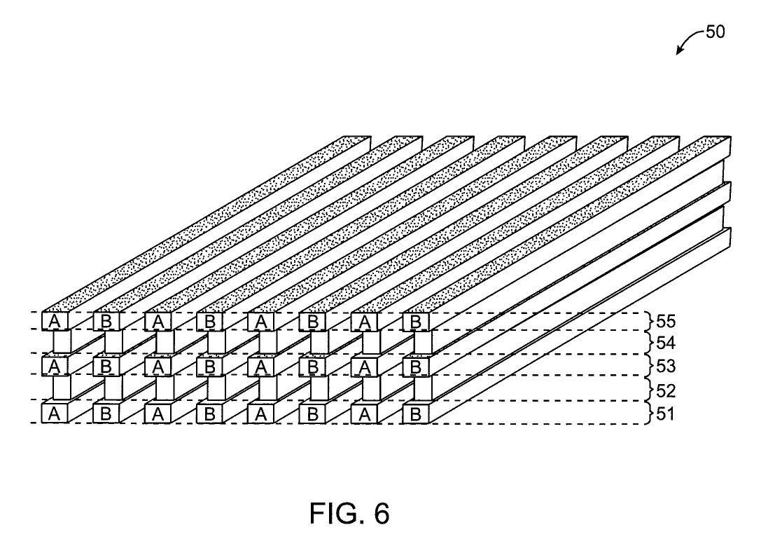

Vertical parallel plate capacitors with bar vias such as capacitor 10 of FIG. 4 may be formed as part of an integrated circuit using any suitable semiconductor fabrication process. One potential fabrication process that may be used is illustrated by FIGS. 6-8.

FIG. 6 illustrates a capacitor 50 with bar vias in which the metal lines, vias, and bar vias lines in each interconnect layer are formed using two separate lithography-and-etch sequences. The via and metal interconnect layers that make up each interconnect layer in capacitor 50 are formed using a single set of deposition processes (e.g., a single dielectric deposition is used to deposit the electric for the interconnect layer and a single metal deposition is used to fill etched vias, bar via trenches, and metal trenches with copper). This type of fabrication process is sometimes referred to as a damascene fabrication process.

In the example illustrated in FIGS. 6-8, layers 51 and 52 of capacitor 50 may be formed using a first set of processes, layers 53 and 54 may be formed using a second set of processes, layer 55 and a corresponding via interconnect layer (not shown) may be formed using a third set of processes, and subsequent interconnect layers may be formed in subsequent steps. As an example, layers 51 and 52 may correspond to the “M2” metal interconnect layer and the “V2 via interconnect layer of FIG. 5, respectively, layer 53 may be the “M3” layer, layer 55 may be the “M5” layer, and layer 54 may be the “V3” layer.

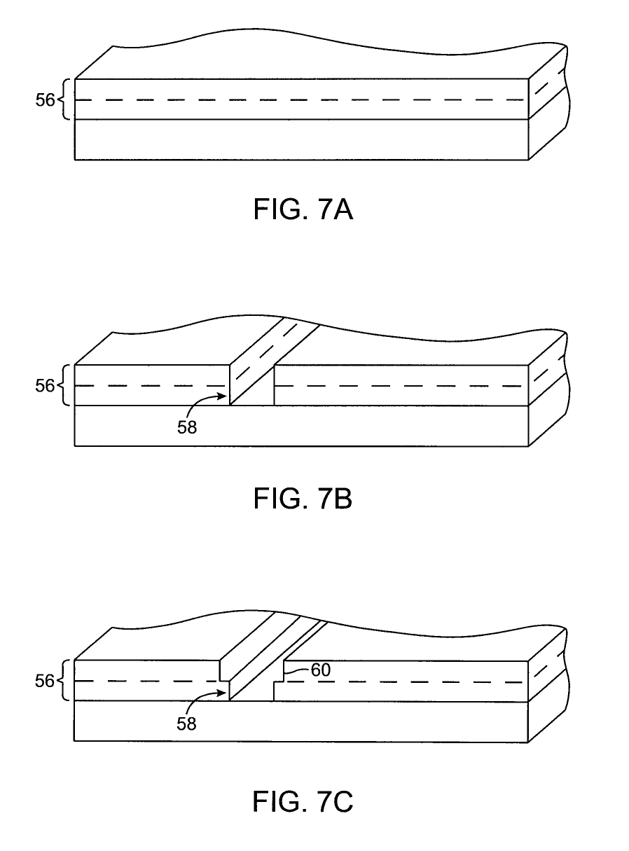

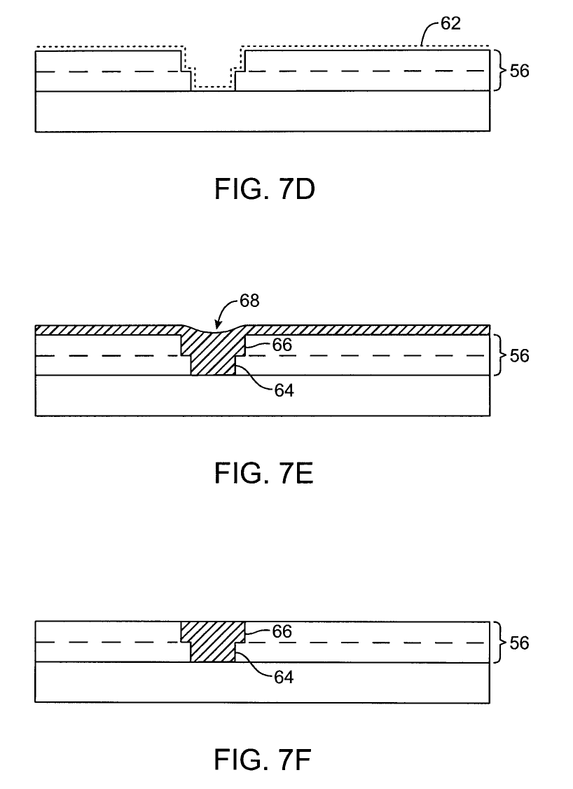

FIGS. 7A, 7B, 7C, 7D, 7E, and 7F are cross-sectional views of the formation of a portion of a dielectric stack in which a capacitor with bar vias such as capacitors 10 and 50 is formed. Only a single bar via structure and metal line structure is shown in FIGS. 7A, 7B, 7C, 7D, 7E, and 7F. However, in general, a large number of vias, bar via structures, and metal line structures may be simultaneously formed as part of each interconnect layer in a dielectric stack (e.g., as part of one of more capacitors and as part of other interconnect circuits).

As a first step in the fabrication process used to form an interconnect layer in a dielectric stack such as stack 30 of FIG. 5, the dielectric for an entire interconnect layer 56 is deposited as illustrated in FIG. 7A. The interconnect layer 56 may be any of the interconnect layers in a dielectric stack such as the “M1” and “V1” interconnect layer of FIG. 5, the “M2” and “V2” interconnect layer, etc. While there are no structures illustrated in the layer below the interconnect layer 56, generally there will be conductive structures such as metal lines, via structures, or tungsten-based vias in each of the layers of the dielectric stack.

The dielectric for interconnect layer 56 may be deposited using any suitable deposition process. For example, the dielectric for the interconnect layer 56 may be deposited using physical vapor deposition, chemical vapor deposition, electrochemical deposition, molecular beam epitaxy, atomic layer deposition, or any other suitable deposition process.

After the dielectric for the interconnect layer 56 has been deposited, portions of the dielectric in interconnect layer 56 such as portion 58 are removed to begin the formation of via structures for the interconnect layer 56 as illustrated in FIG. 7B. With integrated circuit capacitors with bar vias such as capacitors 10 and 50 of FIGS. 4 and 6, respectively, the via structures may be bar vias that are elongated in length relative to their widths and heights.

Bar via trenches in the dielectric of an interconnect layer may be formed using a first lithography-and-etch sequence (e.g., a first patterned removal process). The bar via trenches may be formed using any suitable process such as photolithographic photoresist patterning in combination with dry etching, wet etching, plasma etching, or any other suitable process to remove the appropriate portions of the dielectric in the interconnect layer 56.

As illustrated by FIG. 7C, portions of the dielectric in interconnect layer 56 such as portion 60 corresponding to conductive structures in the metal interconnect portion of layer 56 may be removed using a second lithography-and-etch sequence (e.g., a second patterned removal process).

Following the removal of appropriate portions of the dielectric in interconnect layer 56 (i.e., portions 58 and 60 that respectively correspond to via and metal line structures), a thin layer such as layer 62 may be deposited as illustrated by FIG. 7D. With one suitable arrangement, layer 62 may be a layer sometimes referred to as a copper barrier seed that helps to reduce copper diffusion into the dielectric of layer 56. Layer 56 may also act as a seed layer to facilitate the deposition of a subsequent metal layer (e.g., by electrochemical growth techniques). Typically, it is desirable to minimize the thickness of layer 56 while ensuring its effectiveness.

As shown in FIG. 7E, the vias (i.e., the bar vias 64) and the metal lines 66 of the interconnect layer 56 may be formed with a single deposition process. With one suitable arrangement, copper may be deposited (grown) over the entire interconnect layer 56 so that is fills the voids formed in the dielectric of layer 56 that correspond to the via and metal line structures. With this type of arrangement, the upper surface of dielectric layer 56 may be uneven or may be covered with a sheet of excess conductive copper. For example, there may be an uneven portion such as depression 68.

If necessary, the upper portion of the interconnect layer 56 may be planarized as illustrated in FIG. 7F. Planarization of the interconnect layer 56 may facilitate the manufacture of dielectric stacks with larger numbers of interconnect layers. With one suitable arrangement, the interconnect layer 56 can be planarized using a chemical mechanical polishing (CMP) process. In general, any suitable process may be used to perform planarization. The planarization process will generally help to remove uneven portions such as depression 68 of FIG. 7E and the sheet of excess conductive copper visible in FIG. 7E.

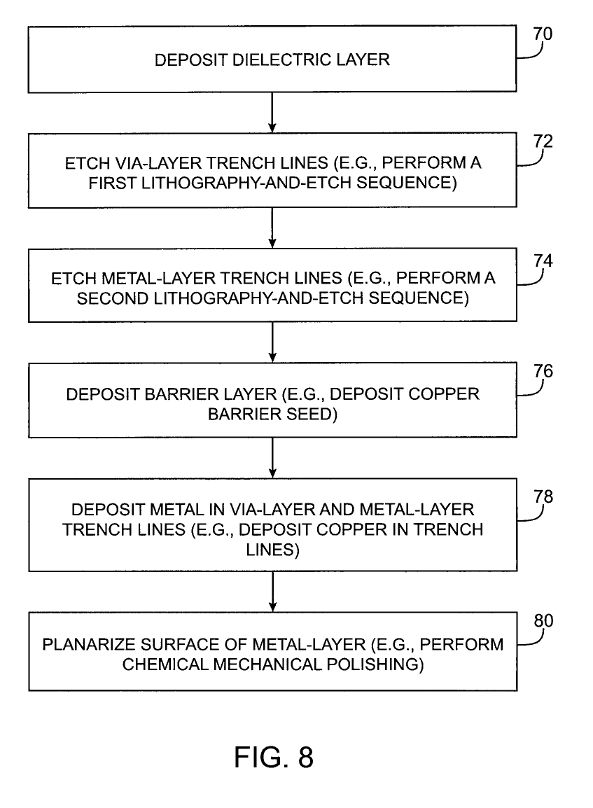

The steps involved in forming capacitor 50 of FIG. 6, a portion of which is shown in FIGS. 7A, 7B, 7C, 7D, 7E, and 7F, are illustrated in the flowchart of FIG. 8.

At step 70, the dielectric layer for an interconnect layer is deposited. The dielectric layer may correspond to both a via interconnect layer and a metal interconnect layer that make up the interconnect layer. As described in connection with FIG. 7A, the dielectric layer may be deposited using any suitable fabrication process.

At step 72, the via-layer trenches may be etched into the dielectric. The via-layer trenches may correspond to the bar vias of the capacitor 50 of FIG. 6. The via-layer trenches may be etched using a first lithography-and-etch sequence as described in connection with FIG. 7B.

At step 74, the metal-layer trenches may be etched into the dielectric. The metal-layer trenches may correspond to the metal lines of the capacitor 50 and may be etched using a second lithography-an-etch sequence as described in connection with FIG. 7C. If desired, the via-layer trenches and metal-layer trenches (i.e., the bar via trenches and metal line trenches) in the capacitor may both be formed during the via-layer etching of step 72. This is because the etching operations of step 72 may involve etching through both the via-layer interconnect layer and a metal-layer interconnect layer directly above the via-layer interconnect layer using a single mask pattern and etch process. The trenches that are formed in this way may be filled with a conductive material to form both the metal lines and the bar vias in the capacitor. With this type of arrangement, the metal-layer etching of step 74 may be performed to etch trenches for metal-layer interconnect lines associated with interconnect circuitry, rather than trenches for metal-layer lines associated with the capacitor. The via-layer and metal-layer trenches associated with the capacitor may be masked with photoresist during the etch operations of step 74 to avoid further etching and potential alignment issues.

A barrier layer may be deposited in step 76. For example, a copper barrier seed layer such as the copper barrier seed layer 62 of FIG. 7D may be deposited using a thin layer deposition process.

The etched via-layer trenches and metal-layer trenches may be filled with metal in step 78. With one suitable arrangement, a copper deposition is used to fill the via-layer and metal-layer trenches in the interconnect layer (e.g., as shown in FIG. 7E).

In step 80, the upper surface of the interconnect layer may be planarized. With one suitable arrangement, the metal-layer interconnect surface (i.e., the upper surface of the interconnect layer) may be planarized using a chemical mechanical polishing process (e.g., so that it appears similar to FIG. 7F).

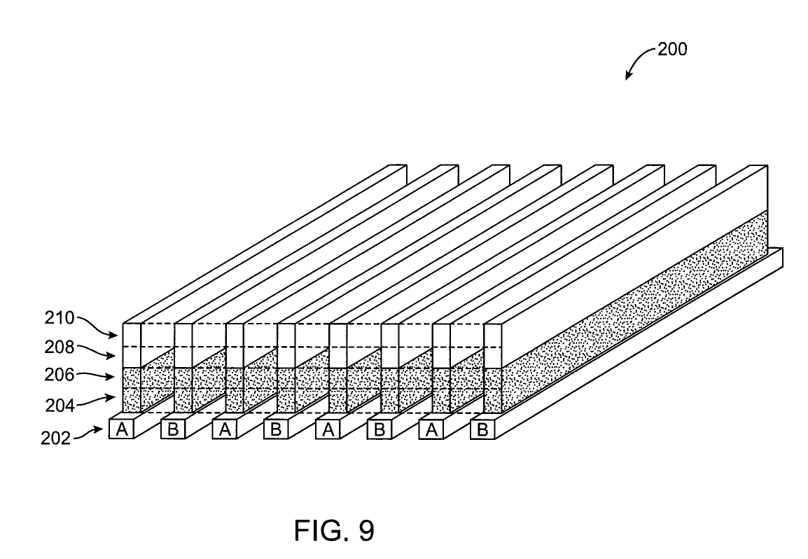

FIG. 9 illustrates a capacitor 200 with bar vias in which the metal lines and bar vias in each layer of the capacitor 200 may be formed using a single lithography-and-etch sequence. A second lithography-and-etch sequence may also be performed on other portions of the dielectric stack in which capacitor 200 is formed. The second lithography-and-etch sequence may be used to form interconnect circuitry that is not related to the capacitor 200 and circuitry that is used to connect to the capacitor 200, as examples.

The via and metal interconnect layers that make up each interconnect layer in capacitor 200 may be formed using a single set of deposition processes (e.g., a single dielectric deposition process may be used to deposit the dielectric and a single metal deposition process may be used to fill the etched vias, bar via trenches, and metal trenches with copper). This type of fabrication process may sometimes be referred to as a modified dual-damascene fabrication process.

In the example illustrated in FIGS. 9-11, layers 202 and 204 of capacitor 200 may be formed in a first set of fabrication processes, layers 206 and 208 may be formed in a second set of processes, layer 210 and a corresponding via interconnect layer (not shown) may be formed in third set of processes, and subsequent interconnect layers may be formed in subsequent sets of processes, as desired.

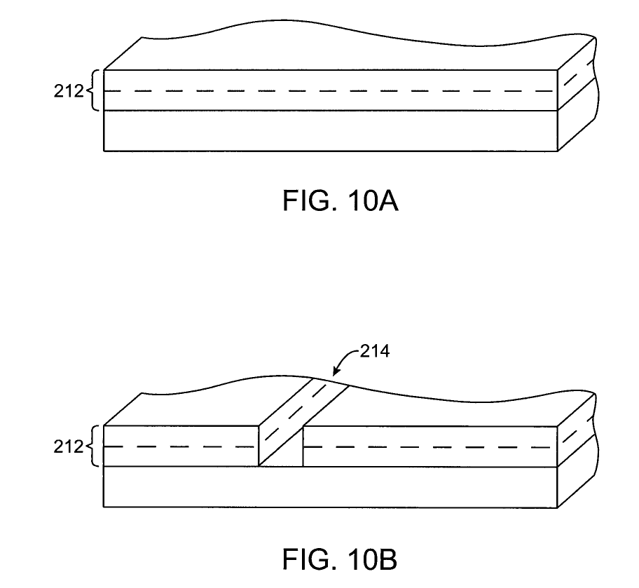

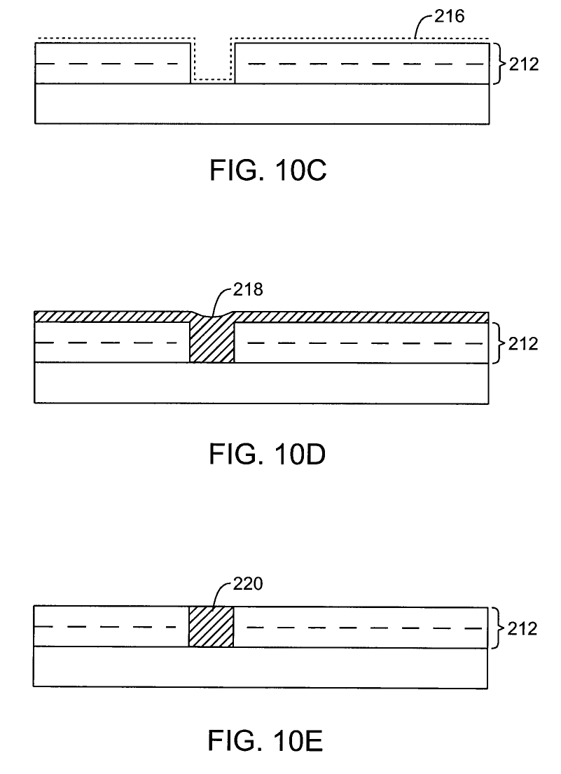

FIGS. 10A, 10B, 10C, 10D, and 10E are cross-sectional views of the formation of a portion of a dielectric stack in which a capacitor with bar vias such as capacitors 10 and 200 is formed.

As a first step in the fabrication process used to form a dielectric stack with a capacitor such as capacitor 10 or 200, the dielectric for an entire interconnect layer 212 is deposited as illustrated in FIG. 10A. The interconnect layer 212 may be any of the interconnect layers in a dielectric stack such as the “M1” and “V1” interconnect layer of FIG. 5, the “M2” and “V2” interconnect layer, etc. The dielectric for interconnect layer 212 may be deposited using any suitable deposition process.

After the dielectric for the interconnect layer 212 has been deposited, portions of the dielectric in interconnect layer 212 such as portion 214 may be removed to begin the formation of the capacitor structures for the interconnect layer 212 as illustrated in FIG. 10B. With integrated circuit capacitors with bar vias such as capacitors 200 of FIG. 9, the portion 214 that is removed from each interconnect layer to form a layer of the capacitor 200 corresponds to both the bar via and the metal line portions in that layer of the capacitor 200.

The bar via trenches and metal trenches may be formed using a single lithography-and-etch sequence. The bar via trenches and metal trenches may be formed using any suitable fabrication process such as a plasma etch.

If desired, the single lithography-and-etch sequence used to form the bar via trenches and metal trenches may also involve etching via-layer structures in other portions of the dielectric stack in which capacitor 200 is formed (i.e., to form interconnect circuitry). If desired, a second lithography-and-etch sequence may also be performed to etch metal-layer structures (e.g., in portions of the dielectric stack that are not associated with a capacitor such as capacitor 200). With one suitable arrangement, when a second lithograph-and-etch process is performed to etch metal-layer structures in other portions of the dielectric stack, a mask may be used to cover the portions of the dielectric stack corresponding to a capacitor such as capacitor 200 (e.g., to avoid further etching of the capacitor).

Following the removal of appropriate portions of the dielectric in interconnect layer 212, a thin layer such as layer 216 may be deposited as illustrated by FIG. 10C. Layer 216 may be a layer sometimes referred to as a copper barrier seed that helps to reduce copper diffusion into the dielectric of layer 212.

As shown in FIG. 10D, the conductor for the bar vias and the metal lines of the interconnect layer 212 may be formed with a single deposition process. With one suitable arrangement, copper may be deposited over the entire interconnect layer 212 to fill the voids formed in the dielectric of layer 212 that correspond to the bar via and metal line structures of capacitor 200 (i.e., portion 218 of layer 212).

If desired, the upper portion of the interconnect layer 212 may be planarized as illustrated in FIG. 10E. With one suitable arrangement, the interconnect layer 212 can be planarized using a chemical mechanical polishing (CMP) process.

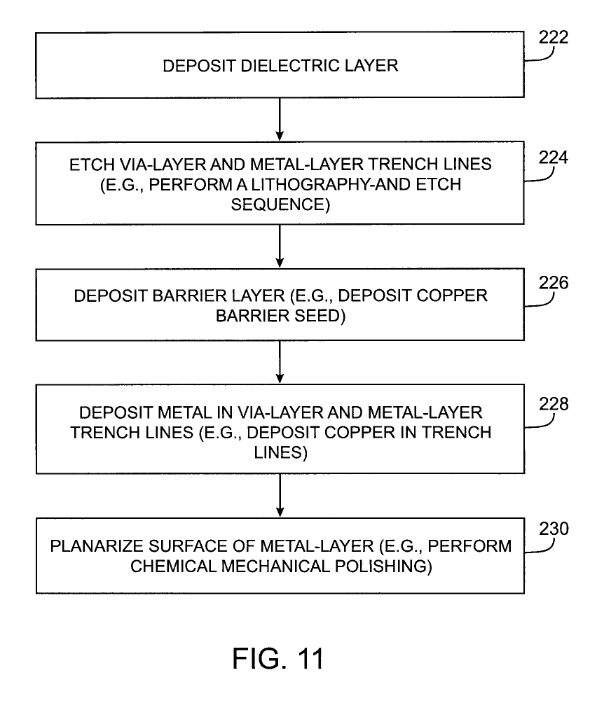

The steps involved in forming capacitor 200 of FIG. 9, a portion of which is shown in FIGS. 10A, 10B, 10C, 10D, and 10E, are illustrated in the flowchart of FIG. 11.

At step 222, the dielectric layer for an interconnect layer is deposited. The dielectric layer may correspond to both a via interconnect layer and a metal interconnect layer that together make up the interconnect layer.

At step 224, a single lithography-and-etch sequence may be used to form via-layer and metal-layer trenches in the dielectric deposited in step 222.

A barrier layer may be deposited in step 226. For example, a copper barrier seed layer such as the copper barrier seed layer 216 of FIG. 10C may be deposited using a thin layer deposition process.

The etched via-layer trenches and metal-layer trenches may be filled with metal in step 228. With one suitable arrangement, a copper deposition step may be used to fill the via-layer and metal-layer trenches in the interconnect layer (e.g., as shown in FIG. 10D).

In step 230, the upper surface of the interconnect layer may be planarized. With one suitable arrangement, a chemical mechanical polishing process may be used to planarize the upper surface of the interconnect layer. The planarization process may also serve to remove any metal deposited in step 228 that is not within a metal-layer trench (e.g., such as the metal above the upper surface of layer 212 in FIG. 10D that has been removed in FIG. 10E).

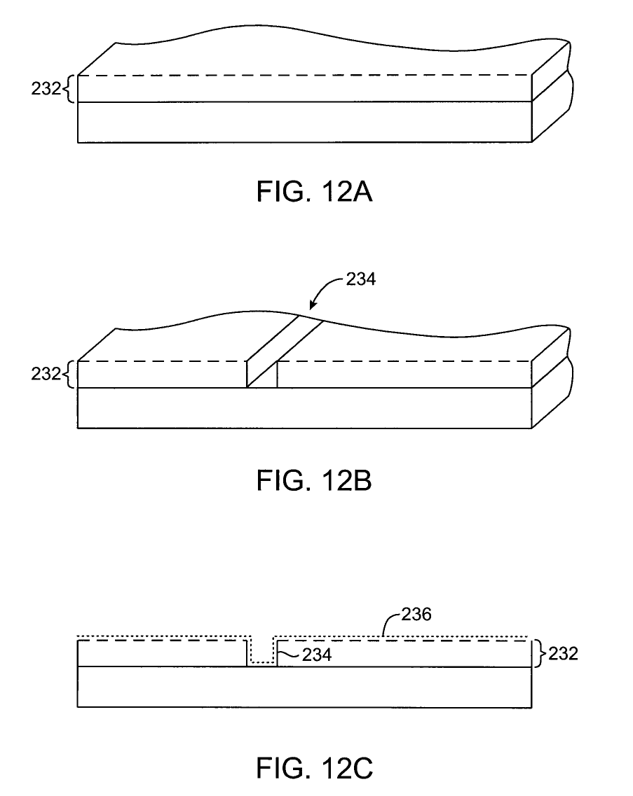

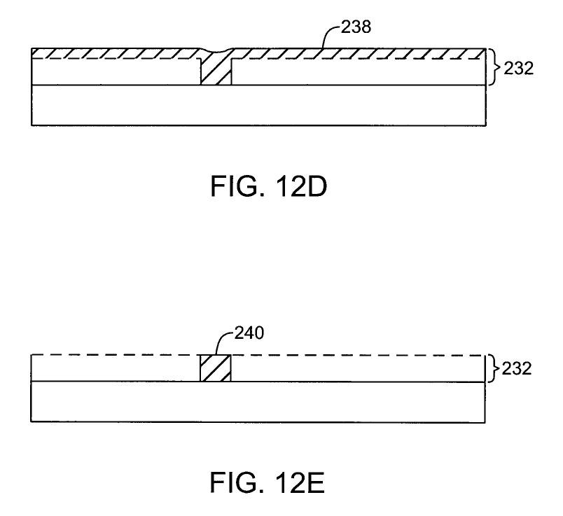

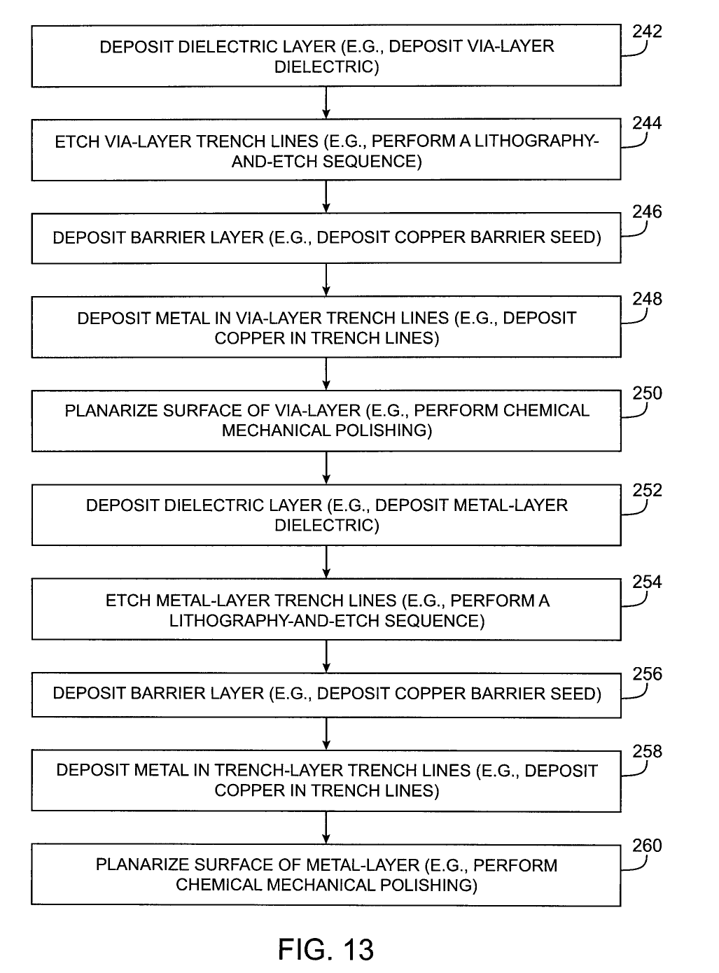

In the example illustrated in FIGS. 12 and 13, a semiconductor fabrication process in which each via-layer interconnect layer is formed independent of each metal-layer interconnect layer is described. This type of fabrication process is sometimes referred to in the fabrication industry as a single damascene fabrication process.

FIGS. 12A, 12B, 12C, 12D, and 12E are cross-sectional views of the formation of a portion of a dielectric stack that includes a capacitor with bar vias such as capacitor 10. Only a single interconnect structure is shown in FIGS. 12A, 12B, 12C, 12D, and 12E. However, in general, a large number of interconnect structures such as vias, bar vias, and metal lines will be simultaneously formed as part of each interconnect layer. In the case of single damascene fabrication, via-layer structures such as vias and bar vias are formed simultaneously. Metal-layer structures are also formed simultaneously but are formed separately from the via-layer structures in the single damascene fabrication process.

As a first step in the fabrication process used to form a dielectric stack with a capacitor such as capacitor 10, the dielectric for a portion of an interconnect layer is deposited. For example, as illustrated in FIG. 12A, the dielectric for via-layer interconnections or for metal-layer interconnects may be deposited (e.g., as layer 232). The layer 232 may be any of the half-interconnect layers in a dielectric stack such as the “M1”, “V1”, “M2”, “V2”, . . . , or “V8” layer of FIG. 5.

After the dielectric for layer 232 has been deposited, portions of the dielectric in layer 232 such as portion 234 may be removed to begin the formation of the capacitor structures for layer 232 as illustrated in FIG. 12B. With integrated circuit capacitors with bar vias such as capacitors 200 of FIG. 9, the portions such as portion 234 that are removed from each layer 232 (i.e., the trenches) to form a layer of the capacitor 200 correspond to either bar vias or metal lines of that layer of the capacitor 200. The portions that are removed from each layer 232 will likely also include circuitry in other portions of the dielectric stack that do not correspond to the capacitor 200.

The bar via trenches or metal trenches may be formed using a single lithography-and-etch sequence. If desired, the single lithography-and-etch sequence used to form bar via trenches or metal trenches in layer 232 may also involve simultaneously etching via-layer structures or metal-layer structures in other portions of the dielectric stack in which capacitor 200 is formed (i.e., to form interconnect circuitry).

Following the removal of appropriate portions of the dielectric in layer 232, a thin layer such as layer 236 may be deposited as illustrated by FIG. 12C. Layer 236 may be a layer sometimes referred to as a copper barrier seed that helps to reduce copper diffusion into the dielectric of layer 212.

As shown in FIG. 12D, the bar vias or the metal lines of layer 232 may be formed with an appropriate deposition process. With one suitable arrangement, copper may be deposited over the layer 232 and fill the voids formed in the dielectric of layer 232 that correspond to the bar vias or metal lines of capacitor 200 (i.e., portion 234 of layer 232).

The upper portion of the interconnect layer 232 may be planarized as illustrated in FIG. 12E. With one suitable arrangement, layer 232 can be planarized using a chemical mechanical polishing (CMP) process.

After planarization, the operations illustrated in FIG. 12A, 12B, 12C, 12D, and 12E may be repeated (e.g., to form additional bar vias or metal layer lines).

Illustrative steps involved in using a single damascene fabrication process to form a capacitor such as capacitor 200 of FIG. 9, a portion of which is shown in FIGS. 12A, 12B, 12C, 12D, and 12E, are illustrated in the flowchart of FIG. 13. The flowchart of FIG. 13 describes the steps involved in forming a complete interconnect layer (i.e., forming a via interconnect layer and a metal interconnect layer).

At step 242, the dielectric for a via interconnect layer may be deposited. The dielectric layer may correspond to a via interconnect layer that is to become part of an interconnect layer that includes both the via layer and a metal layer.

At step 244, a lithography-and-etch sequence may be used to form via-layer via holes and bar via trenches in the dielectric deposited in step 242.

A barrier layer may be deposited in step 246. For example, a copper barrier seed layer such as the copper barrier seed layer 236 of FIG. 12C may be deposited.

The etched via-layer via holes and bar via trenches may be filled with metal to form vias and bar vias in step 248. With one suitable arrangement, a copper deposition process may be used to fill the via-layer via holes and bar via trenches (e.g., as shown in FIG. 12D) as well as via holes in other portions of the dielectric stack.

In step 250, the upper surface of the via-layer interconnect dielectric layer may be planarized. With one suitable arrangement, a chemical mechanical polishing process may be used to planarize the upper surface of the via-layer interconnect layer.

At step 252, the dielectric for a metal interconnect layer may be deposited. With one suitable arrangement, the dielectric layer may correspond to a metal interconnect layer that is part of the interconnect layer just above via-layer formed in steps 242, 244, 246, 248, and 250.

At step 254, a lithography-and-etch sequence may be used to form metal-layer trenches in the dielectric deposited in step 252.

A barrier layer may be deposited in step 256. For example, a copper barrier seed layer such as the copper barrier seed layer 236 of FIG. 12C may be deposited.

The etched metal-layer trenches may be filled with metal in step 258. With one suitable arrangement, a copper deposition step may be used to fill the metal-layer trenches (e.g., as shown in FIG. 12D).

If desired, the upper surface of the metal-layer may be planarized in step 260 (e.g., using a chemical mechanical polishing process). In general, the dielectric stack formed as part of the steps of FIG. 13 may be planarized at any suitable time such as after fabrication of an entire interconnect layer, after fabrication of a via-layer interconnect layer, after fabrication of a metal-layer interconnect layer, or after the fabrication of a via-layer interconnect layer and after the fabrication of a metal-layer interconnect layer. The operations of FIG. 13 may be repeated multiple times thereby forming multiple interconnect layers containing vertical parallel plate capacitor structures.

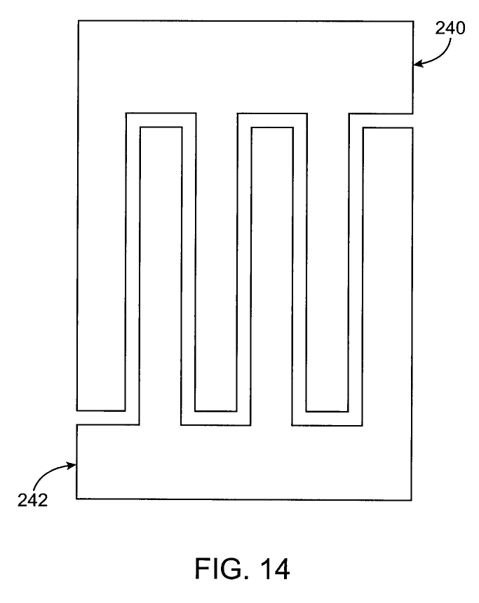

FIG. 14 is a top view of a metal-oxide-metal capacitor with bar vias such as capacitors 10, 50, and 200 showing how the metal lines and bar vias of the capacitor may be shorted together to form a first capacitor terminal 240 and a second capacitor terminal 242. The terminals 240 and 242 may facilitate the electrical connection of the capacitor to circuitry (i.e., interconnect circuitry) and may help to evenly distribute electrical charges across the structure of the capacitor.

As shown in FIG. 14, the metal lines and bar vias of a capacitor may be shorted to a first terminal 240 and a second terminal 242. If desired the terminals 240 and 242 may be formed across multiple interconnect layers. With this type of arrangement, the metal lines and bar vias in each interconnect layer may be electrically connected to capacitor terminals in that interconnect layer, rather than being indirectly connected to capacitor terminals in another interconnect layer.

Terminals 240 and 242 may be formed from any suitable structures. For example, terminals 240 and 242 may be formed from metal lines in metal-layer interconnect layers associated with the capacitor and the metal lines associated with each of the terminals may be connected together using a plurality of vias. If desired, terminals 240 and 242 may be formed from metal lines in the associated metal-layer interconnect layers and bar vias in the via-layer interconnect layers. The metal lines and bar vias used to form terminals 240 and 242 may be similar in shape and size and may contribute to the capacitance of the capacitor (e.g., because of the proximity of capacitor terminal 240 to the metal lines and bar vias associated with terminal 242 and the proximity of terminal 242 to the metal lines and bar vias associated with terminal 240).

The foregoing is merely illustrative of the principles of this invention and various modifications can be made by those skilled in the art without departing from the scope and spirit of the invention.

What is claimed is:

1. A capacitor formed in a dielectric stack in an integrated circuit, comprising:
a plurality of bar vias; and
a plurality of metal lines that overlap and run parallel to the bar vias.

2. The capacitor defined in claim 1 wherein the dielectric stack includes alternating via-layer interconnect layers that contain the bar vias and metal-layer interconnect layers that contain the metal lines and wherein the bar vias in a given via-layer interconnect layer are parallel to each other.

3. The capacitor defined in claim 1 wherein the dielectric stack includes alternating via-layer interconnect layers that contain the bar vias and metal-layer interconnect layers that contain the metal lines and wherein the metal lines in a given metal-layer interconnect layer are parallel to each other.

4. The capacitor defined in claim 1 wherein each of the bar vias has a width and a length that is greater than its width and wherein each of the metal lines has a width and a length that is greater than its width.

5. The capacitor defined in claim 1 wherein the dielectric stack includes alternating via-layer interconnect layers that contain the bar vias and metal-layer interconnect layers that contain the metal lines and wherein each of the bar vias and each of the metal lines are parallel to each other.

6. The capacitor defined in claim 5 wherein the bar vias comprise copper lines formed in the via-layer interconnect layer.

7. The capacitor defined in claim 5 wherein each of the bar vias in a given via-layer interconnect layer is associated with and electrically connected to a respective one of the metal lines in a given metal-layer interconnect layer.

8. The capacitor defined in claim 5 wherein each of the bar vias in a given via-layer interconnect layer has a width and a length greater than its width and is associated with and electrically connected along its length to a respective one of the metal lines in a given metal-layer interconnect layer.

9. The capacitor defined in claim 8 wherein the metal lines comprise planarized copper lines.

10. The capacitor defined in claim 9 wherein the length of each of the bar vias is at least five times its width and wherein the length of each of the metal lines is at least five times its width.

11. The capacitor defined in claim 10 wherein the width of each of the bar vias is equal to the width of each of the metal lines.

12. The capacitor defined in claim 10 wherein the width of each of the bar vias is less than the width of each of the metal lines.

13. A capacitor in an integrated circuit having a plurality of interconnect layers, the capacitor comprising:
a plurality of bar vias each having a width and a length greater than its width; and
a plurality of metal lines each having a length and being connected along its length to a respective one of the bar vias.

14. The capacitor defined in claim 13 wherein the bar vias each have a width and wherein the metal lines each have a width that is equal to the width of the bar vias.

15. The capacitor defined in claim 13 wherein the bar vias each have a width and wherein the metal lines each have a width that is greater than the width of the bar vias.

16. The capacitor defined in claim 13 wherein the integrated circuit comprises at least six interconnect layers, wherein each interconnect layer comprises a via-layer interconnect layer and a metal-layer interconnect layer, wherein the via-layer interconnect layer and the metal-layer interconnect layer each comprise an insulator, wherein each bar via comprises a conductive copper pathway in the insulator of a given via-layer interconnect layer, and wherein each metal line comprises a conductive copper pathway in the insulator of a given metal-layer interconnect layer.

17. The capacitor defined in claim 13 wherein the interconnect layers comprise alternating via-layer interconnect layers and metal-layer interconnect layers and wherein the bar vias comprise a plurality of bar vias in at least two of the via-layer interconnect layers and wherein the metal lines comprise a plurality of metal lines in at least three of the metal-layer interconnect layers.

18. A capacitor in an integrated circuit dielectric stack comprising:
a dielectric layer formed by depositing dielectric material in the dielectric stack;
bar via trenches formed by removing portions of the dielectric material, each bar via trench having a width and a length that is at least twice its width; and
bar vias formed by depositing a conductive material in the bar via trenches.

19. The capacitor defined in claim 18 further comprising:
multiple interconnect layers in the dielectric stack some of which include the bar vias and some of which include conductive lines in metal-layer interconnect layers, wherein the conductive lines are connected to respective bar vias and wherein the multiple interconnect layers are formed by repeatedly depositing dielectric material in the dielectric stack, removing portions of the dielectric material to form trenches, and depositing conductive material in the trenches.

20. The capacitor defined in claim 18 further comprising:
metal-layer trenches formed in a metal-layer interconnect layer in the dielectric stack; and
metal lines formed by depositing conductive material in the metal-layer trenches, wherein each metal line overlaps and is electrically connected along its length to at least one of the bar vias.

21. The capacitor defined in claim 20 wherein the bar via trenches and the metal-layer trenches in the metal-layer interconnect layer comprise trench structures formed by etching through the dielectric layer in a single etching operation.

22. The capacitor defined in claim 21 further comprising:
metal interconnect trenches in the metal-interconnect layer formed by etching the metal-interconnect layer while masking the bar via trenches and the metal-layer trenches.

23. The capacitor defined in claim 18 wherein the dielectric stack includes alternating via-layer interconnect layers of dielectric and metal-layer interconnect layers of dielectric and wherein the bar vias are formed in the via-layer interconnect layers, the capacitor further comprising:
metal lines formed in at least some of the metal-layer interconnect layers that run parallel to the bar vias.
